(19) United States
(12) Patent Application Publication
(10) Pub. No.: US 2016/0187414 A1
(43) Pub. Date: Jun. 30, 2016

(54) DEVICE HAVING FINFETS AND METHOD FOR MEASURING RESISTANCE OF THE FINFETS THEREOF

(71) Applicant: United Microelectronics Corp., Hsin-Chu City (TW)

(72) Inventor: Hung-Chan Lin, Tainan City (TW)

(21) Appl. No.: 14/585,212

(22) Filed: Dec. 30, 2014

(51) Int. Cl. G01R 31/26; G01R 27/02; H01L 21/66; H01L 29/788; H01L 27/088; H01L 29/10

(52) U.S. Cl. CPC G01R 31/2623; H01L 27/0886; H01L 29/1095; H01L 22/32; H01L 27/0883; H01L 29/788; G01R 27/02

(57) ABSTRACT

A semiconductor device with FinFETs is provided, including a plurality of fin structures and a plurality of gate structures. The fin structures are disposed on a substrate, stretching along a first direction and spaced from each other by a first space. The fin structures comprise a selected fin structure. The gate structures are disposed on the substrate, stretching along a second direction. The gate structures comprise a first gate structure and a second gate structure which is adjacent to the first gate structure. A part of the selected fin structure and a part of the first gate structure form a first FinFET. A part of the selected fin structure and a part of the second gate structure form a second FinFET. The first FinFET is in depletion mode and the second FinFET is in enhancement mode. A method for measuring a resistance of FinFETs in a semiconductor device is provided.

### BACKGROUND OF THE INVENTION

1. Field of the Invention

The present invention is related to a device with FINFETs and method for measuring a resistance thereof, and more particularly, to device having FINFETs in enhance-mode and depletion-mode.

2. Description of the Prior Art

In recent years, as various kinds of consumer electronic products are being constantly modified towards increased miniaturization, the size of semiconductor components are modified to be reduced accordingly, in order to meet high integration, high performance, low power consumption, and the demands of products.

However, with the increasing miniaturization of electronic products, current planar FETs no longer meet the requirements of the products. Thus, non-planar FETs such as Fin-shaped FETs (FinFET) have been developed, which includes a three-dimensional channel structure. The manufacturing processes of FinFET devices can be integrated into traditional logic device processes, and thus are more compatible. In addition, since the three-dimensional structure of the FinFET increases the overlapping area between the gate and the substrate, the channel region is controlled more effectively. This therefore reduces drain-induced barrier lowering (DIBL) effect and short channel effect. Moreover, the channel region is longer for the same gate length. Therefore, the current between the source and the drain is increased. In current years, the development of the FinFETs is still aiming to devices with smaller scales.

However, many problem would raise because the shrinkage of the FinFETs size. For example, measuring a resistance value of a FinFET would become more difficult because additional components should be added into original circuits, taking extra space and affecting original design of the products. Thus, there is still a need to develop a novel device to overcome abovementioned problem.

### SUMMARY OF THE INVENTION

The present invention therefore provides a device having FinFETs, wherein the resistance value thereof can be easily measured without affecting other devices.

According to one embodiment, a semiconductor device with FinFETs is provided. The semiconductor device includes a plurality of fin structures and a plurality of gate structures. The fin structures are disposed on a substrate, stretching along a first direction and spaced from each other by a first space, wherein the fin structures comprise a selected fin structure. The gate structures are disposed on the substrate, stretching along a second direction, wherein the gate structures comprise a first gate structure and a second gate structure which is adjacent to the first gate structure. A part of the selected fin structure and a part of the first gate structure form a first FinFET. A part of the selected fin structure and a part of the second gate structure form a second FinFET. The first FinFET is in depletion mode and the second FinFET is in enhancement mode.

According to another embodiment, a method for measuring a resistance of FinFETs in a semiconductor device is provided. First, a semiconductor device is provided, which comprises a plurality of fin structures and a plurality of gate structures. The fin structures are disposed on a substrate, stretching along a first direction and spaced from each other by a first space, wherein the fin structures comprise a selected fin structure. The gate structures are disposed on the substrate, stretching along a second direction, wherein the gate structures comprise a first gate structure and a second gate structure which is adjacent to the first gate structure. A part of the selected fin structure and a part of the first gate structure form a first FinFET. A part of the selected fin structure and a part of the second gate structure form a second FinFET. The first FinFET is in depletion mode and the second FinFET is in enhancement mode. A resistance value of at least the first FinFET is measured.

The semiconductor device provided in the present invention has at least one FinFET in depletion mode, so no additional voltage or via plug is required to apply to said depletion FinFET. Consequently, the space and the cost can be saved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 show schematic diagrams of a semiconductor device having FinFETs according to one embodiment of the present invention.

FIG. 3 show schematic diagrams of a semiconductor device having FinFETs according to another embodiment of the present invention.

FIG. 4 and FIG. 5 show schematic diagrams of details components of FinFETs according to different embodiment of the present invention.

FIG. 6 and FIG. 7 show schematic diagrams of a method for measuring a resistance of the semiconductor device having FinFETs according to one embodiment of the present invention.

FIG. 8 and FIG. 9 show schematic diagrams of a method for measuring a resistance of the semiconductor device having FinFETs according to different embodiments of the present invention.

### DETAILED DESCRIPTION

To provide a better understanding of the presented invention, preferred embodiments will be made in detail. The preferred embodiments of the present invention are illustrated in the accompanying drawings with numbered elements.

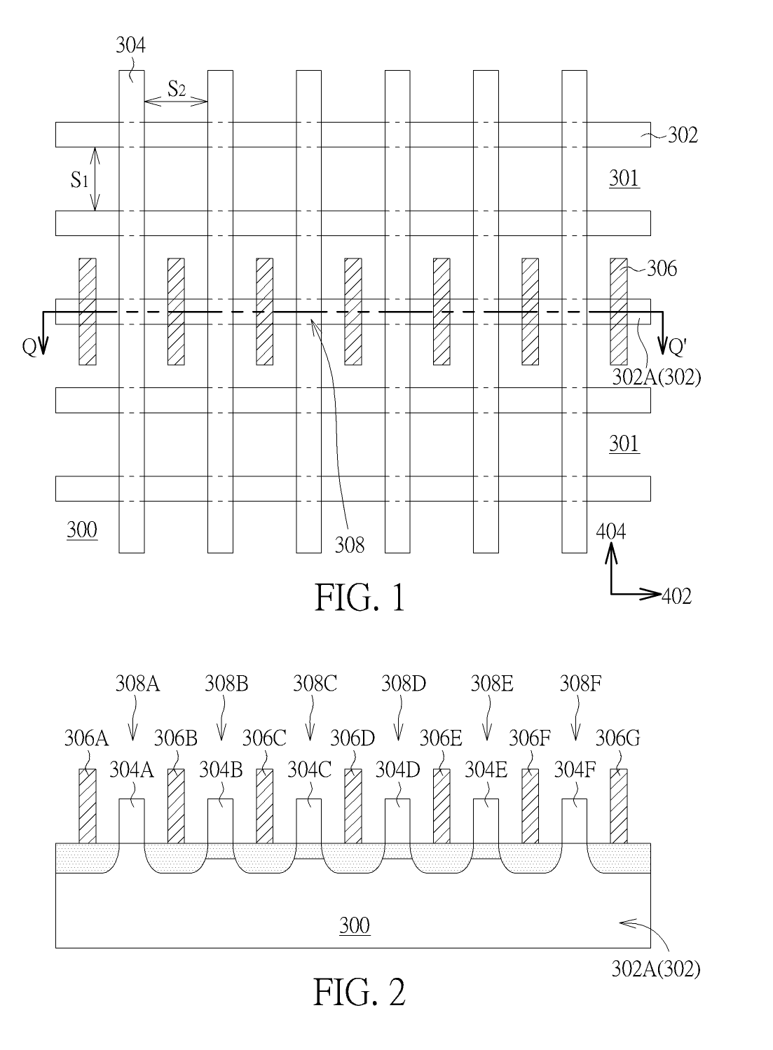

Please refer to FIG. 1 and FIG. 2, showing schematic diagrams of a semiconductor device having FinFETs according to one embodiment of the present invention, wherein FIG. 1 shows a top view and FIG. 2 shows a cross-sectional view taken along line QQ′ in FIG. 1. Please see FIG. 1 first. A plurality of fin structures 302 stretching along a first direction 402 and a plurality of gate structures 304 stretching along a second direction are disposed on a substrate 300. Preferably, the first direction 402 is substantially perpendicular to the second direction 404. In one embodiment, the substrate 300 is composed of a silicon containing material. Silicon containing materials include, but are not limited to, Si, single crystal Si, polycrystalline Si, SiGe, single crystal silicon germanium, polycrystalline silicon germanium, or silicon doped with carbon, amorphous Si and combinations and multi-layered materials thereof. The semiconductor substrate 300 may also be composed of other semiconductor materials, such as germanium, and compound semiconductor substrates, such as type III/V semiconductor substrates, e.g., GaAs. Although the semiconductor substrate 300 is depicted as a bulk semiconductor substrate, the arrangement of a semiconductor on an insulator substrate, such as silicon-on-insulator (SOI) substrates, is also suitable for the semiconductor substrate 300.

As shown in FIG. 1, along the first direction 402, the fin structures 302 and a plurality of shallow trench isolations (STIs) 301 are arranged 302 alternatively. The method for forming the fin structure 302 and the STIs 301 includes, for example, forming a patterned hard mask layer (not shown) on the substrate 300, performing an etching process to form a plurality of trenches (not shown) in the substrate 300, filling an insulating material such as SiO₂ into the trenches, and performing a planarization and/or etching process to form said STIs 301. The protruding portion of the substrate 300 above STI 301 becomes the fin structures 302. In one embodiment, the fin structures 302 are arranged in a fix pitch manner, meaning that each fin structure 302 is spaced from each other by a first space S1. Regarding to the second direction 404, the gate structure 304 are disposed on the fin structures 302 and the STIs 301, thus the gate structures 304 and the fin structures 302 intersect with each other. In one embodiment, each gate structure 304 is spaced from each other by a second space S2.

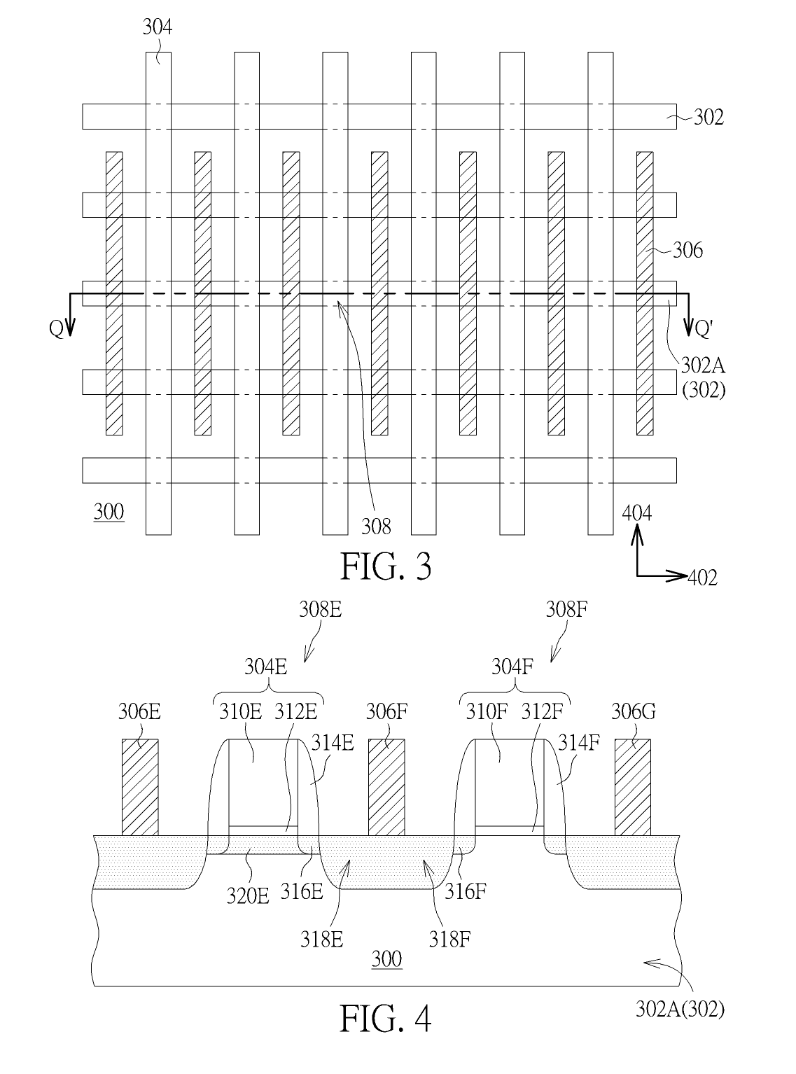

The semiconductor device in the present invention further comprise a plurality of contact plugs 306 disposed on the same fin structure 302A and each of which is disposed between each two gate structures 304. One contact plug 306 at least straddles over one fin structure 302, for example, the fin structure 302A. In another embodiment, as shown in FIG. 3, one contact plug 306 may straddle over more than one fin structures 302.

The intersecting fin structures 302 and the gate structures 304 constitute a plurality of FinFETs 308. For the detail descriptions for the FinFETs, please see the cross-sectional view of FIG. 2. As illustrated, the fin structure 302A and the gate structures 304A, 304B, 304C, 304D, 304E, 304F constitute a plurality of FinFETs 308A, 308B, 308C, 308D, 308E, 308F, wherein the contact plugs 306A, 306B, 306C, 306D, 306E, 306F, 306G are disposed on the fin structure 302A and arranged alternative with the gate structures 306. It is one salient feature of the present invention that in two adjacent FinFETs, one is in depletion mode and another is in enhancement mode. For example, the FinFET 308FE is in depletion mode and the FinFET 308E is in enhancement mode.

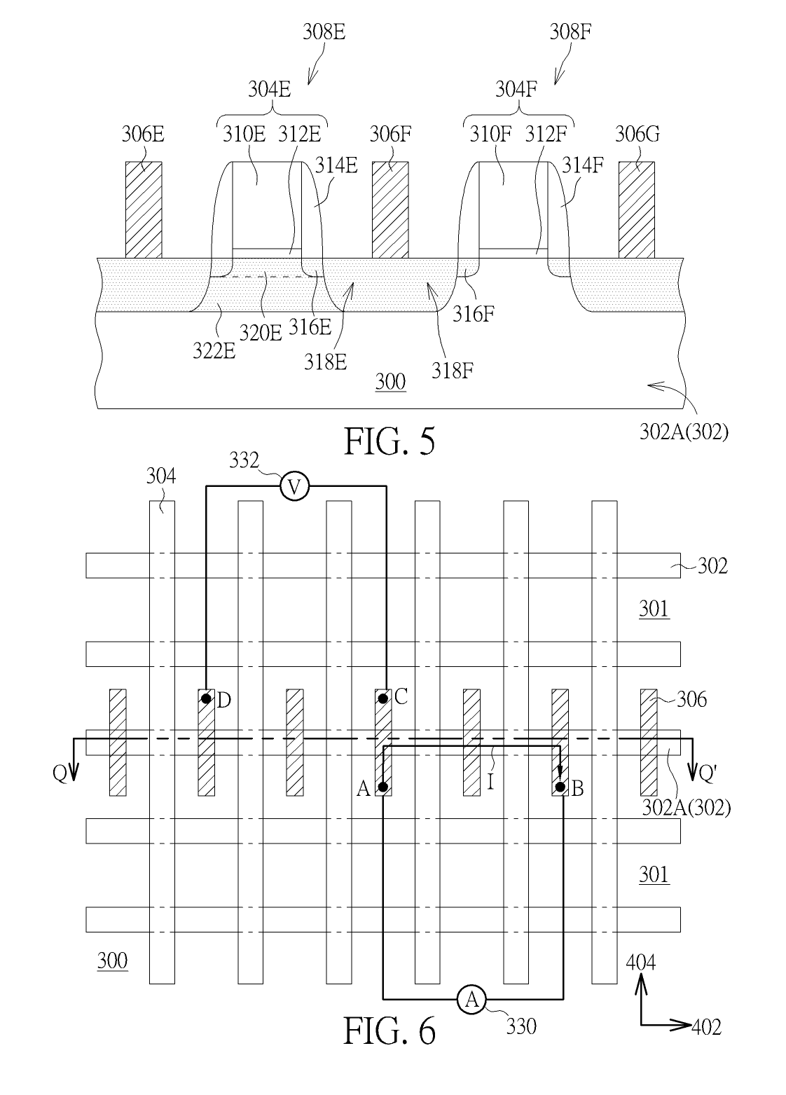

Please see FIG. 4, which shows details components of FinFET 308E and FinFET 308F. Regarding to the enhance mode FinFET 308F, in one embodiment, it is comprised of the gate structure 304F, a spacer 314F, a light doped drain (LDD) region 316F and a source/drain region 318F. In one embodiment, the gate structure 304F comprises a conductive layer 310F and a gate dielectric layer 312F. The conductive layer 310F can include metal or poly-silicon. The gate dielectric layer 312F includes SiO₂ or high-k dielectric materials, such as a material having dielectric constant greater than 4. The spacer 314F is disposed on at least a sidewall of the gate structure 304F. The spacer 314F can be a single layer or a composite layer, which is composed of high temperature oxide (HTO), silicon nitride, silicon oxide or silicon nitride (HCD-SiN) formed by hexachlorodisilane, Si₂Cl₆). The LDD region 316F is disposed in the fin structure 302A and has a predetermined conductive type dopant. When the FinFET 308F is a P-type transistor, the predetermined conductivity type dopant is P type dopant, such as boron (B) and/or boron fluoride (BF). Conversely, when the FinFET 308F is an N-type transistor, the predetermined conductivity type dopant an N-type dopant such as arsenic (As) and/or phosphorus (P) and/or antimony (Sb), but are not limited thereto. The source/drain region 318F is disposed in the fin structure 302A (or the substrate 300) at at least one side of the gate structure 304F and has a dopant with the same conductive type with the LDD region 316F. In one embodiment, the spacer 314F and the LDD region 316F are optional. Since the FinFET 308F is in enhancement mode, a threshold voltage (Vt) should be applied to the gate structure 304F so as to turn on the FinFET 308F.

Regarding to the depletion mode FinFET 308E, in one embodiment, it is comprised of the gate structure 304E, a spacer 314E, an LDD region 316E and a source/drain region 318E. In one embodiment, the gate structure 304E comprises a conductive layer 310E and a gate dielectric layer 312E. The components of the FinFET 308E are similar to those of the FinFET 308F and are not repeated for the sake of simplicity. It is noted that the FinFET 308E and the FinFET 308F can share the same source/drain region 318E, 318F. Comparing to the FinFET 308F, the FinFET 308E further comprises a channel doped region 320E disposed in the fin structure 302A under the gate structure 304E, being between and directly contacting the LDD region 316E (or the source/drain region 318E in the embodiment that the LDD region 316D is omitted). The channel doped region 320E has a dopant with the same conductive type with the LDD region 316E (or the source/drain region 318E). In one embodiment, a concentration of the dopant in the channel doped region 320E is substantially equal to or slightly smaller than that of the LDD region 316E. In another embodiment, when the LDD region 316E is omitted, the concentration thereof is substantially equal to or slightly smaller than that of the source/drain region 316E. In one embodiment, a depth of the channel doped region 320E is substantially equal to that of the LDD region 316E. It is noted that since the FinFET 308E is in depletion mode, no threshold voltage (Vt) is required to apply to the gate structure 304E.

Please refer to FIG. 5, showing a schematic diagram of details components of FinFET 308E and FinFET 308F according to another embodiment of the present invention. As shown in FIG. 5, besides the channel doped region 320E, FinFET 308E can further include a deep doped region 322E disposed in the fin structure 322A (or the substrate 300) under the channel doped region 322E, being between and directly contacting the source/drain region 318E. The deep doped region 322E has a dopant with the same conductive type with the channel doped region 320E. In one embodiment, a concentration of the dopant in the deep doped region 322E is smaller than that of the channel doped region 320E. In another embodiment, they can be the same, meaning that the deep doped region 322E and the channel doped region 320E can be regarded as one single doped region can be formed in the same fabrication process. It is understood that the depletion mode FinFET 308E is not limited to abovementioned embodiment, and can be any type of depletion mode transistor.

As shown in FIG. 4 and FIG. 5, the contact plugs 306E, 306F, 306G land on the source/drain region 318E, 318F of the FinFETs 308E, 308F, respectively. In one embodiment, the contact plugs 306E, 306F, 306G are metal0 contact plug (also called M0 contact) and top surfaces thereof are substantially equal to top surfaces of the gate structures 304E, 304F, but are not limited thereto. It is understood that besides the above mentioned embodiment, the FinFETs can further comprise other components, such as an epitaxial structure (not shown) in the fin structure 302A at one side of the gate structure 304E in which a part thereof can serve as the source/drain region 318E, or a silicide layer (not shown) disposed between the contact plug 306F and the source/drain region 318E, or a contact etching stop layer (CESL) (not shown) with stress covering the FinFET 304E, or an inter-dielectric layer (ILD) (not shown) disposed between the contact plug 306F and the FinFET 308E.

Please refer back to FIG. 2. In one embodiment, more than one FinFET can be in depletion mode. For example, the FinFETs 308B, 308C, 308D, 308E are in depletion mode, and the FinFETs 308A, 308F are in enhancement mode. It is noted that in one preferred embodiment, the depletion FinFETs are directly adjacent to each other and the out-most one is directly adjacent to an enhancement FinFET.

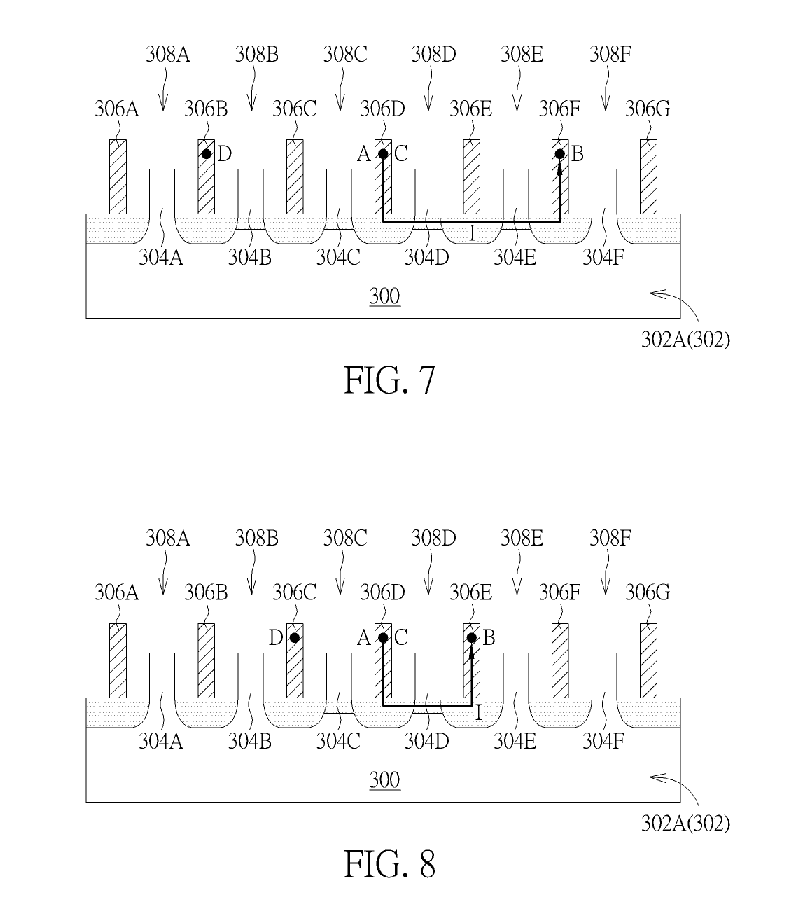

According to the novel structure of the FinFETs, it is easier to measure resistance value of the FinFETs. Please refer to FIG. 6 and FIG. 7, showing schematic diagrams of a method for measuring a resistance of the semiconductor device having FinFETs according to one embodiment of the present invention. In one embodiment, the FinFETs can be used as a testkey to measure their resistance by a “four-terminal sensing process (also called “Kelvin process”).” As shown in FIG. 6 and FIG. 7, four terminals (can also be regarded as “sensing wires”) including first terminal A, second terminal B, third terminal C and fourth terminal D are electrically connected to the contact plugs 306 and can transport sensing signals to/from a voltmeter and/or an ammeter. For example, the first terminal A and the third terminal C are connected to the contact plug 306D, wherein the first terminal A is located at one side of the fin structure 302A and the third terminal C is located at another side. The second terminal B is connected to the contact plug 306F and the fourth terminal D is connected to the contact plug 306B. The first terminal A and the second terminal B connect to an ammeter 330 outside the chip through a metal interconnection system or pads (not shown) for example. The third terminal C and the fourth terminal D connect to a voltmeter 332 via the metal interconnection system or pads (not shown) for example. As shown in FIG. 7, the FinFETs between the second terminal B and the fourth terminal D, namely the FinFETs 308B, 308C, 308D, 308E are in depletion mode, while the FinFETs outside the second terminal B and the fourth terminal D, namely the FinFETs 308A, 308F, are in depletion mode. The four-terminal sensing process is performed by the following steps:

(a) supplying a current I from first terminal A to second terminal B;

(b) measuring the current value of current I; and

(c) measuring a voltage drop value between third terminal C and fourth terminal D.

The resistance value of the FinFET passed by the current I can be calculated by the formula (R=Voltage drop/current value).

Since the FinFETs 308B, 308C, 308D, 308E between second terminal B and fourth terminal D are in depletion mode, no additional threshold voltage is required to turn on the FinFETs 308B, 308C, 308D, 308E. In other words, the gate structures 304B, 304C, 304D, 304E are floating and no additional contact as well as metal interconnection system is electrically connected to said gate structures. On the other hand, regarding to the enhancement mode FinFETs 308A, 308F, as shown in FIG. 6, both the gate structure 304A of the FinFET 308A and the gate structure 304F of the FinFET 308F should electrically connect to via plugs 324.

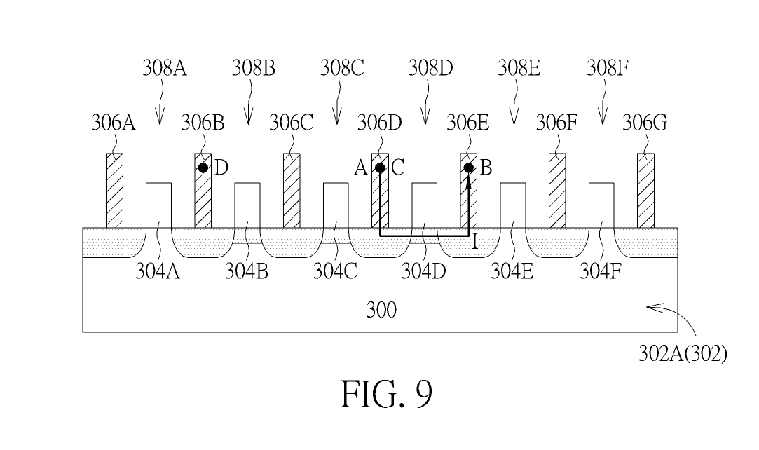

Please refer to FIG. 8 and FIG. 9, showing schematic diagrams of a method for measuring a resistance of the semiconductor device having FinFETs according to different embodiments of the present invention. Depending on different measuring requirements, the terminals (or sensing wire) can connect to different contact plugs and the FinFETs in depletion mode can be adjusted based on it. As shown in FIG. 8, the second terminal B is connect to the contact plug 306E and the fourth terminal D is connected to the contact plug 306C, so the current I flows from contact plug 306D to contact plug 306E. In this embodiment, only FinFETs 308C, 308D are in depletion mode. In another embodiment, the depletion mode FinFETs are not symmetrical along the contact plug 306D which first terminal A and third terminal C are connected to. As shown in FIG. 9, two FinFETs 308B, 308C between first terminal A and fourth terminal D are in depletion mode while one FinFET 308D between first terminal A and second terminal B is in depletion mode.

In summary, the present invention provides a device having FinFETs and a method for measuring a resistance of the FinFETs. Since at least one the FinFETs is in depletion mode, no additional voltage or via plug is required to apply to said depletion FinFETs, the space and the cost can be saved.

Those skilled in the art will readily observe that numerous modifications and alterations of The semiconductor device and method may be made while retaining the teachings of the invention. Accordingly, the above disclosure should be construed as limited only by the metes and bounds of the appended claims.

1. A semiconductor device having FinFETs, comprising:
a plurality of fin structures disposed on a substrate, stretching along a first direction and spaced from each other by a first space, wherein the fin structures comprise a selected fin structure; and
a plurality of gate structures disposed on the substrate and stretching along a second direction, wherein the gate structures comprise a first gate structure and a second gate structure which is adjacent to the first gate structure,
wherein a part of the selected fin structure and a part of the first gate structure form a first FinFET, and a part of the selected fin structure and a part of the second gate structure form a second FinFET, the first FinFET comprises a channel doped region in the selected fin structure and between the two source/drain regions and a deep doped region under the channel doped region in the selected fin structure, and the channel doped region and the deep doped region have a dopant with same conductive type of the source/drain regions.

2. The semiconductor device having FinFETs according to claim 1, wherein the first FinFET comprises two source/drain regions in the selected fin structure at two sides of the first gate structure, and the source/drain regions have a dopant with a conductive type.

3-4. (canceled)

5. The semiconductor device having FinFETs according to claim 1, wherein the first gate structure is floating.

6. The semiconductor device having FinFETs according to claim 1, wherein the gate structures further comprise a third gate structure adjacent to the first gate structure, and a part of the selected fin structure and a part of the third gate structure form a third FinFET.

7. The semiconductor device having FinFETs according to claim 1, further comprises a plurality of contact plugs disposed on the selected fin structure and arranged in alternation with the gate structures.

8. The semiconductor device having FinFETs according to claim 7, wherein the contact plugs comprise a first contact plug, a second contact plug and a third contact plug, and the first contact plug is disposed between the second contact plug and the third contact plug.

9. The semiconductor device having FinFETs according to claim 8, further comprising:
a first sensing wire and a third sensing wire electrically connected to the first contact plug;
a second sensing wire electrically connected to the second contact plug; and
a fourth sensing wire electrically connected to the third contact plug.

10. The semiconductor device having FinFETs according to claim 9, wherein a plurality of FinFETs are disposed on the selected fin structure and are between the second contact plug and the third contact plug, wherein the plural FinFETs comprise the first FinFET.

11. The semiconductor device having FinFETs according to claim 9, wherein the first sensing wire and the second sensing wire are connected to an ammeter.

12. The semiconductor device having FinFETs according to claim 9, wherein the third sensing wire and the fourth sensing wire are connected to a voltmeter.

13. A method for measuring a resistance of FinFETs in a semiconductor device, comprising:
providing a semiconductor device, comprising:
a plurality of fin structures disposed on a substrate, stretching along a first direction and spaced from each other by a first space, wherein the fin structures comprise a selected fin structure; and
a plurality of gate structures stretching along a second direction and disposed on the substrate, wherein the gate structures comprise a first gate structure and a second gate structure that is adjacent to the first gate structure, wherein a part of the selected fin structure and a part of the first gate structure form a first FinFET, a part of the selected fin structure and a part of the second gate structure form a second FinFET, the first FinFET is in a depletion mode and the second FinFET is in an enhancement mode; and
measuring a resistance value of at least the first FinFET.

14. The method for measuring a resistance of FinFETs in a semiconductor device according to claim 13, wherein the measuring step comprises a four terminal sensing process.

15. The method for measuring a resistance of FinFETs in a semiconductor device according to claim 14, wherein the semiconductor device further comprises a plurality of contact plugs disposed on the selected fin structure and arranged alternative with the gate structures.

16. The method for measuring a resistance of FinFETs in a semiconductor device according to claim 15, wherein the contact plugs comprise a first contact plug, a second contact plug and a third contact plug, and the first contact plug is disposed between the second contact plug and the third contact plug.

17. The method for measuring a resistance of FinFETs in a semiconductor device according to claim 16, wherein the first FinFET is disposed between the second contact plug and the third contact plug.

18. The method for measuring a resistance of FinFETs in a semiconductor device according to claim 16, further comprising:
a first sensing wire and a third sensing wire electrically connected to the first contact plug;
a second sensing wire electrically connected to the second contact plug; and
a fourth sensing wire electrically connected to the third contact plug.

19. The method for measuring a resistance of FinFETs in a semiconductor device according to claim 18, wherein the four terminal sensing process is carried out by:
applying a current between the first sensing wire and the second sensing wire;
measuring the current value; and
measuring a voltage drop between the third sensing wire and the fourth sensing wire.

20. The method for measuring a resistance of FinFETs in a semiconductor device according to claim 19, wherein a resistance value of FinFETs between the first contact plug and the second contact plug is (voltage drop/current value).
